(19) United States
(12) Patent Application Publication
(10) Pub. No.: US 2025/0126998 A1
(43) Pub. Date: Apr. 17, 2025

(54) DISPLAY APPARATUS

(71) Applicant: Samsung Display Co., Ltd., Yongin-si (KR)

(72) Inventors: Jiwon Yeo, Yongin-si (KR); Seungyeon Cho, Yongin-si (KR)

(21) Appl. No.: 18/912,011

(22) Filed: Oct. 10, 2024

(30) Foreign Application Priority Data
Oct. 13, 2023 (KR) 10-2023-0137035

(51) Int. Cl. H10K 59/131

(52) U.S. Cl. CPC H10K 59/131

(57) ABSTRACT

A display apparatus includes a substrate including a display area, and a peripheral area surrounding at least a portion of the display area in plan view, a first data line in the display area, and extending in a second direction, a second data line apart from the first data line in a first direction crossing the second direction, extending in the second direction, and having a length that is greater than a length of the first data line, and a branch line connected to the first data line, and protruding from the first data line in the first direction.

### CROSS-REFERENCE TO RELATED APPLICATION

The present application claims priority to, and the benefit of, Korean Patent Application No. 10-2023-0137035, filed on Oct. 13, 2023, in the Korean Intellectual Property Office, the entire disclosure of which is incorporated herein by reference.

### BACKGROUND

### 1. Field

One or more embodiments relate to a display apparatus.

### 2. Description of the Related Art

A display apparatus visually displays data. A display apparatus may provide an image by using light-emitting diodes. The usage of display apparatuses has been diversified, and various designs have been attempted to improve the quality of display apparatuses.

### SUMMARY

One or more embodiments include a display apparatus.

Additional aspects will be set forth in part in the description which follows and, in part, will be apparent from the description, or may be learned by practice of the presented embodiments of the disclosure.

According to one or more embodiments, a display apparatus includes a substrate including a display area, and a peripheral area surrounding at least a portion of the display area in plan view, a first data line in the display area, and extending in a second direction, a second data line apart from the first data line in a first direction crossing the second direction, extending in the second direction, and having a length that is greater than a length of the first data line, and a branch line connected to the first data line, and protruding from the first data line in the first direction.

The branch line may include a first branch line extending in the second direction, and a second branch line connecting the first branch to the first data line and extending in the first direction.

The first data line and the branch line may be at a same layer, and may include a same material.

The display apparatus may further include a first bridge line apart from the first data line in the first direction and extending in the second direction, wherein the first data line and the first bridge line are connected to each other.

An end of the first bridge line may be connected to an end of the first data line.

The first data line and the first bridge line may be at a same layer, and may include a same material.

A thickness of the first bridge line in the first direction may be greater than a thickness of the first data line in the first direction.

According to one or more embodiments, a display apparatus includes a substrate including a display area having a circular shape, and a peripheral area surrounding at least a portion of the display area in plan view, a third data line arranged in the display area, and extending in a second direction, and a second bridge line apart from the third data line in a first direction crossing the second direction, extending in the second direction, and connected to the third data line.

An end of the third data line may be connected to an end of the second bridge line.

The third data line and the second bridge line may be at a same layer, and may include a same material.

A thickness of the second bridge line in the first direction may be greater than a thickness of the third data line in the first direction.

The display apparatus may further include a third bridge line connected to a first end of the third data line, and extending in the first direction.

The third bridge line and the third data line may be at different respective layers.

A thickness of the third bridge line in the second direction may be greater than a thickness of the third data line in the first direction.

The display apparatus may further include a fourth bridge line apart from the third data line in the first direction, extending in the second direction, and connected to the third bridge line.

The third data line may be arranged between the second bridge line and the fourth bridge line.

The third bridge line and the fourth bridge line may be at different respective layers.

The fourth bridge line and the third data line may be at a same layer, and may include a same material.

The display apparatus may further include a fifth bridge line connected to a second end of the third data line, and extending in the first direction.

The fifth bridge line and the third data line may be at different respective layers.

### BRIEF DESCRIPTION OF THE DRAWINGS

The above and other aspects of certain embodiments of the disclosure will be more apparent from the following description taken in conjunction with the accompanying drawings, in which:

FIG. 1 is a schematic plan view of a portion of a display apparatus according to one or more embodiments;

FIG. 2 is an equivalent circuit diagram of a pixel included in the display apparatus of FIG. 1;

FIG. 3 is a schematic cross-sectional view of a display apparatus according to one or more embodiments;

FIG. 4 is a schematic enlarged plan view of a first data line and a branch line of FIG. 1;

FIG. 5 is a schematic plan view of a portion of a display apparatus according to one or more embodiments;

FIG. 6 is a schematic enlarged plan view of a first data line, a first bridge line, and a branch line of FIG. 5;

FIG. 7 is a schematic plan view of a display apparatus according to one or more embodiments;

FIG. 8 is a schematic enlarged plan view of region A of FIG. 7;

FIG. 9 is a schematic plan view of a display apparatus according to one or more embodiments;

FIG. 10 is a schematic enlarged plan view of region B of FIG. 9;

FIG. 11 is a schematic plan view of a display apparatus according to one or more embodiments; and

FIG. 12 is a schematic enlarged plan view of region C of FIG. 11.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

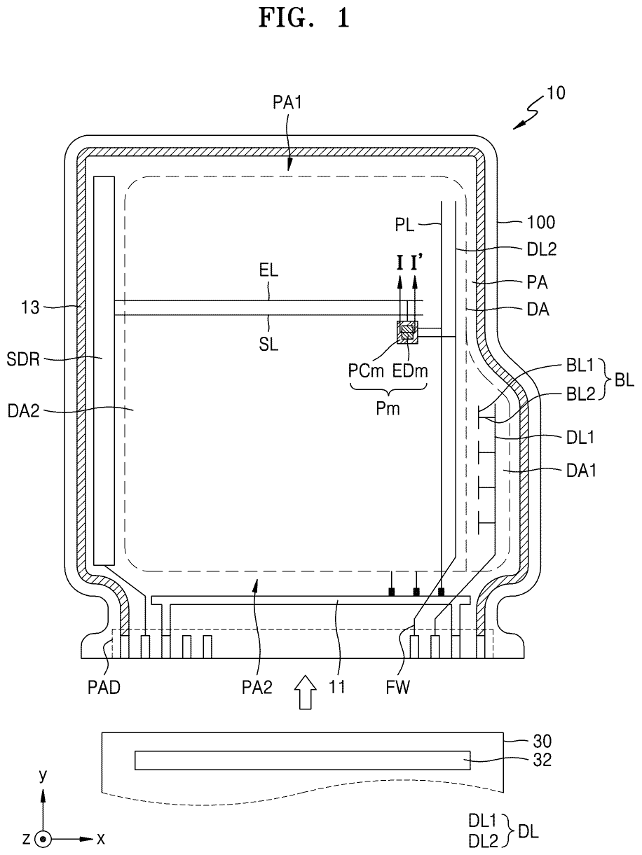

FIG. 1 is a schematic plan view of a portion of a display apparatus 10 according to one or more embodiments. As illustrated in FIG. 1, the display apparatus 10 according to one or more embodiments may include a substrate 100 that may include a display area DA, and a peripheral area PA outside the display area DA. An image may be displayed in the display area DA. The peripheral area PA may be a type of non-display area in which no display devices are arranged. The display area DA may be entirely surrounded by the peripheral area PA (e.g., in plan view).

The display area DA of the display apparatus 10 may have an amorphous shape rather than a rectangular shape. For example, the display area DA of the display apparatus 10 may not have a constant length from any point along a first direction (for example, an x direction or a −x direction) toward a second direction (for example, a y direction or a −y direction). In detail, the display area DA may include a first display area DA1 and a second display area DA2. A length of the first display area DA1 in the first direction (for example, the x direction or the −x direction) may be different from a maximum distance of the second display area DA2 in the first direction (for example, the x direction or the −x direction). Also, a length of the first display area DA1 in the second direction (for example, the y direction or the −y direction) may be different from a maximum distance of the second display area DA2 in the second direction (for example, the y direction or the −y direction). However, the disclosure is not limited thereto. According to one or more other embodiments, the display area DA of the display apparatus 10 may have a circular shape.

The substrate 100 may include glass, metal, or polymer resins. When the substrate 100 has a flexible or bendable property, the substrate 100 may include polymer resins, such as polyethersulfone, polyacrylate, polyetherimide, polyethylene naphthalate, polyethylene terephthalate, polyphenylene sulfide, polyarylate, polyimide, polycarbonate, or cellulose acetate propionate. However, various modifications of the substrate 100 may be possible. For example, the substrate 100 may have a multi-layered structure including two layers including the polymer resins described above, and a barrier layer between the two layers, the barrier layer including an inorganic material, such as silicon oxide, silicon nitride, silicon oxynitride, or the like.

The display apparatus 10 may provide an image by using a plurality of pixels Pm arranged in the display area DA of the substrate 100. Each of the pixels Pm may include a pixel circuit PCm, and a display device EDm electrically connected to the pixel circuit PCm. The pixel circuit PCm may include at least one thin-film transistor TFT configured to control emission, a degree of emission, etc. of the display device EDm. The pixel circuit PCm may be arranged to overlap the display device EDm.

Hereinafter, an organic light-emitting display apparatus will be described as an example of the display apparatus 10 according to one or more embodiments. That is, a case where the display device EDm is an organic light-emitting device will be described. However, the display apparatus 10 according to the disclosure is not limited thereto. For example, the display apparatus 10 according to the disclosure may include an inorganic light-emitting display apparatus, an inorganic electroluminescent (EL) display apparatus, or a quantum dot light-emitting display apparatus. For example, an emission layer of the display device provided in the display apparatus 10 may include an organic material, an inorganic material, or an organic material and quantum dots. Also, the display apparatus 10 may include quantum dots and may convert a wavelength of light.

The pixel circuit PCm included in the pixel Pm in the display area DA may be electrically connected to outer circuits arranged in the peripheral area PA. A scan-driving circuit SDR, a pad portion PAD, a driving voltage supply line 11, and a common voltage supply line 13 may be arranged in the peripheral area PA.

The scan-driving circuit SDR may be arranged at a side of the display area DA. The scan-driving circuit SDR may be connected to one or more of the pixel circuits PCm through a scan line SL, and may be configured to apply a scan signal. The scan-driving circuit SDR may be connected to one or more of the pixel circuits PCm through an emission control line EL, and may be configured to apply an emission control signal. However, the disclosure is not limited thereto. According to one or more other embodiments, the scan-driving circuit SDR may also be arranged at the other side of the display area DA, and thus, two scan-driving circuits SDR may be provided.

The pad portion PAD may be arranged in a second peripheral area PA2 at a side of the substrate 100. The pad portion PAD may not be covered by an insulating layer, and may be exposed so as to be connected to a display circuit board 30. A display driver 32 may be arranged on the display circuit board 30.

The display driver 32 may be configured to generate a control signal transmitted to the scan-driving circuit SDR. Also, the display driver 32 may be configured to generate a data signal, and the generated data signal may be transmitted to the pixel circuit PCm through a fanout line FW and a data line DL connected to the fanout line FW.

The data line DL may include a first data line DL1 and a second data line DL2. The first data line DL1 and the second data line DL2 may be arranged in the display area DA. In detail, the first data line DL1 may be arranged in the first display area DA1, and the second data line DL2 may be arranged in the second display area DA2.

The first data line DL1 and the second data line DL2 may be arranged to be apart from each other in the second direction (for example, the y direction or the −y direction). A length of the first data line DL1 in the first direction (for example, the x direction or the −x direction) may be different from a length of the second data line DL2 in the first direction (for example, the x direction or the −x direction). The length of the first data line DL1 in the first direction (for example, the x direction or the −x direction) may be less than the length of the second data line DL2 in the first direction (for example, the x direction or the −x direction).

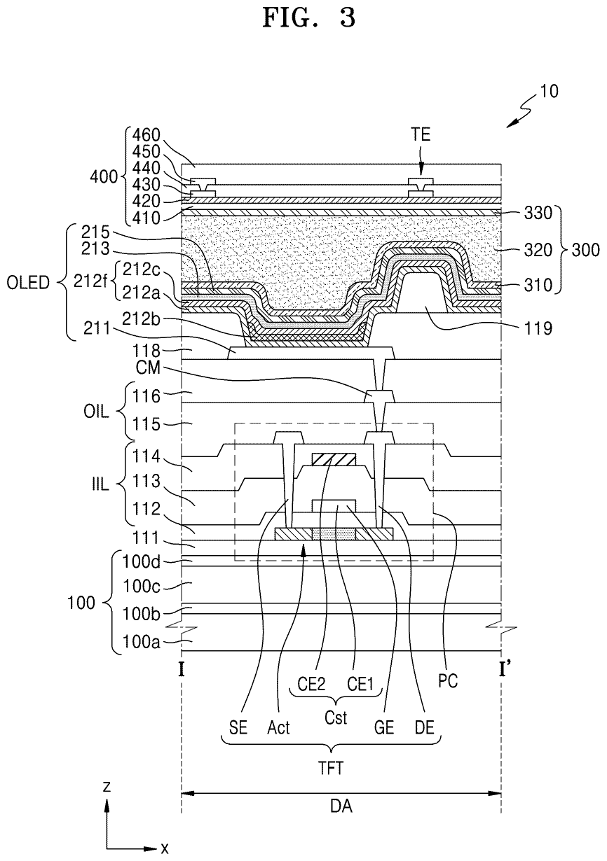

According to one or more embodiments, a branch line BL connected to the first data line DL1 may be arranged in the display area DA. In detail, the branch line BL protruding from the first data line DL1 in the second direction (for example, the y direction or the −y direction) may be arranged in the display area DA. The branch line BL may include a first branch line BL1 and a second branch line BL2. This aspect will be described in more detail with reference to FIG. 3.

The display driver 32 may be configured to supply a driving voltage ELVDD to the driving voltage supply line 11, and to supply a common voltage ELVSS to the common voltage supply line 13. The driving voltage ELVDD may be applied to the pixel circuit PCm through a driving voltage line PL connected to the driving voltage supply line 11, and the common voltage ELVSS may be connected to the common voltage supply line 13, and may be applied to an opposite electrode of the display device EDm.

The driving voltage supply line 11 may be arranged below the display area DA and may have a shape to extend in an x-axis direction. The common voltage supply line 13 may have a loop shape having an open side and may partially surround the display area DA.

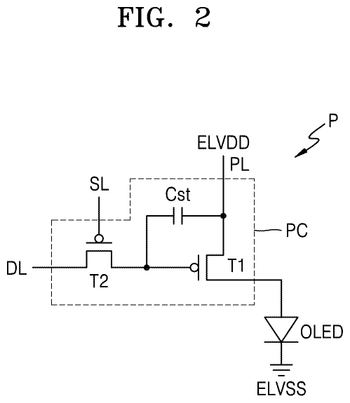

FIG. 2 is an equivalent circuit diagram of a pixel P included in the display apparatus 10 of FIG. 1. Here, the pixel P refers to a pixel indicated by the reference numeral Pm in FIG. 1.

As illustrated in FIG. 2, the pixel P may include a pixel circuit PC and an organic light-emitting diode OLED electrically connected to the pixel circuit PC. The pixel circuit PC refers to the pixel circuit indicated by the reference numeral PCm in FIG. 1, and the organic light-emitting diode OLED refers to the display device indicated by the reference numeral EDm in FIG. 1.

The pixel P may include the organic light-emitting diode OLED as a display element connected to the pixel circuit PC. The pixel circuit PC may include a first thin-film transistor T1, a second thin-film transistor T2, and a storage capacitor Cst. Each pixel P may emit, for example, red, green, or blue light or red, green, blue, or white light through the organic light-emitting diode OLED.

The second thin-film transistor T2 may be a switching thin-film transistor, may be connected to the scan line SL and the data line DL, and may be configured to transmit, to the first thin-film transistor T1, a data voltage input from the data line DL, based on a switching voltage input from the scan line SL. The storage capacitor Cst may be connected to the second thin-film transistor T2 and the driving voltage line PL, and may be configured to store a voltage corresponding to a difference between a voltage received from the second thin-film transistor T2 and a first power voltage ELVDD supplied to the driving voltage line PL.

The first thin-film transistor T1 may be a driving thin-film transistor, may be connected to the driving voltage line PL and the storage capacitor Cst, and may be configured to control a driving current flowing from the driving voltage line PL through the organic light-emitting diode OLED according to a value of the voltage stored in the storage capacitor Cst. The organic light-emitting diode OLED may emit light having a corresponding brightness according to the driving current. An opposite electrode (for example, a cathode) of the organic light-emitting diode OLED may receive a second power voltage ELVSS.

FIG. 2 illustrates that the pixel circuit PC includes two thin-film transistors and one storage capacitor. However, the disclosure is not limited thereto. The number of thin-film transistors and the number of storage capacitors may be variously modified according to the design of the pixel circuit PC. For example, the pixel circuit PC may include two thin-film transistors, as described above, or four or five or more thin-film transistors.

FIG. 3 is a schematic cross-sectional view of a display apparatus according to one or more embodiments. In detail, FIG. 3 is a schematic cross-sectional view of the display apparatus 10 of FIG. 1, taken along the line I-I′.

Referring to FIG. 3, the substrate 100 may include a first base layer 100a, a first barrier layer 100b, a second base layer 100c, and a second barrier layer 100d. According to one or more embodiments, the first base layer 100a, the first barrier layer 100b, the second base layer 100c, and the second barrier layer 100d may be sequentially stacked in a thickness direction of the substrate 100.

At least one of the first base layer 100a and the second base layer 100c may include polymer resins, such as polyethersulfone, polyarylate, polyetherimide, polyethylene naphthalate, polyethylene terephthalate, polyphenylene sulfide, polyimide, polycarbonate, cellulose tri acetate, cellulose acetate propionate, etc.

The first barrier layer 100b and the second barrier layer 100d may reduce or prevent the penetration of external impurities and may include a single layer or layers including an inorganic material, such as silicon nitride (SiNₓ), silicon oxide (SiO₂), and/or silicon oxynitride (SiON).

A buffer layer 111 may be located on the substrate 100. The buffer layer 111 may include an inorganic insulating material, such as SiNₓ, SiON, or SiO₂, and may include a single layer or layers including the inorganic insulating material described above.

An inorganic insulating layer IIL may be located on the buffer layer 111. The inorganic insulating layer IIL may include a first gate-insulating layer 112, a second gate-insulating layer 113, and an interlayer insulating layer 114.

The pixel circuit PC may be arranged in the display area DA. The pixel circuit PC may include the thin-film transistor TFT and the storage capacitor Cst. The thin-film transistor TFT may include a semiconductor layer Act, a gate electrode GE, a source electrode SE, and a drain electrode DE.

The semiconductor layer Act may be located on the buffer layer 111. The semiconductor layer Act may include polysilicon. Alternatively, the semiconductor layer Act may include amorphous silicon, an oxide semiconductor, or an organic semiconductor. The semiconductor layer Act may include a channel area, as well as a drain area and a source area arranged at respective sides of the channel area.

The gate electrode GE may be located on the semiconductor layer Act. The gate electrode GE may overlap the channel area. The gate electrode GE may include a low-resistance metal material. The gate electrode GE may include a conductive material including Mo, Al, Cu, Ti, etc., and may include layers or a single layer including the conductive material described above.

The first gate-insulating layer 112 may be located between the semiconductor layer Act and the gate electrode GE. The first gate-insulating layer 112 may include an inorganic insulating material, such as SiO₂, SiNₓ, SiON, aluminum oxide (Al₂O₃), titanium oxide (TiO₂), tantalum oxide (Ta₂O₅), hafnium oxide (HfO₂), or zinc oxide (ZnO).

The second gate-insulating layer 113 may be located on the gate electrode G. The second gate-insulating layer 113 may cover the gate electrode GE. The second gate-insulating layer 113 may include an inorganic insulating material, such as SiO₂, SiNₓ, SiON, Al₂O₃, TiO₂, Ta₂O₅, HfO₂, or ZnO.

A second storage plate CE2 of the storage capacitor Cst may be located on the second gate-insulating layer 113. The second storage plate CE2 may overlap the gate electrode GE located therebelow. Here, the gate electrode GE and the second storage plate CE2 overlapping each other with the second gate-insulating layer 113 therebetween may be included in the storage capacitor Cst. That is, the gate electrode GE may function as a first storage plate CE1 of the storage capacitor Cst.

As described above, the storage capacitor Cst and the thin-film transistor TFT may be formed to overlap each other. However, the disclosure is not limited thereto. For example, the storage capacitor Cst may be formed not to overlap the thin-film transistor TFT. That is, the first storage plate CE1 of the storage capacitor Cst may be a separate element from the gate electrode GE of the thin-film transistor TFT, and may be apart from the gate electrode GE of the thin-film transistor TFT.

The second storage plate CE2 may include Al, Pt, Pd, Ag, Mg, Au, Ni, Nd, Ir, Cr, Ca, Mo, Ti, W, and/or Cu, and may include a single layer or layers including the materials described above.

The interlayer insulating layer 114 may be located on the second storage plate CE2. The interlayer insulating layer 114 may cover the second storage plate CE2. The interlayer insulating layer 114 may include SiO₂, SiNₓ, SiON, Al₂O₃, TiO₂, Ta₂O₅, HfO₂, ZnO, or the like. The interlayer insulating layer 114 may include a single layer or layers including the inorganic insulating material described above.

Each of the drain electrode DE and the source electrode SE may be located on the interlayer insulating layer 114. Each of the drain electrode DE and the source electrode SE may be connected to the semiconductor layer Act through a contact hole provided in the first gate-insulating layer 112, the second gate-insulating layer 113, and the interlayer insulating layer 114. The drain electrode DE and the source electrode SE may include a highly conductive material. The drain electrode DE and the source electrode SE may include a conductive material including Mo, Al, Cu, Ti, etc., and may include layers or a single layer including the materials described above. For example, the drain electrode DE and the source electrode SE may have a multi-layered structure of Ti/Al/Ti.

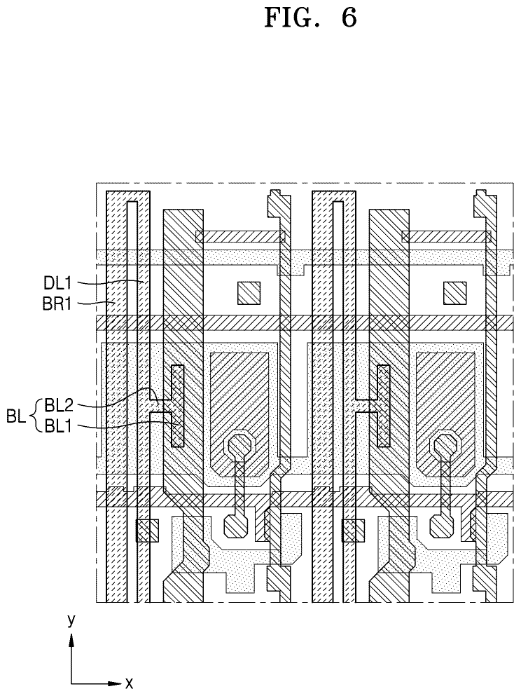

An organic insulating layer OIL may be located on the inorganic insulating layer IIL. The organic insulating layer OIL may include a first organic insulating layer 115 and a second organic insulating layer 116. FIG. 6 illustrates that the organic insulating layer OIL includes two organic insulating layers. However, the disclosure is not limited thereto. The organic insulating layer OIL may include three or four organic insulating layers.

The first organic insulating layer 115 may cover the drain electrode DE and the source electrode SE. The first organic insulating layer 115 may include an organic insulating material, such as a general-purpose polymer such as polymethylmethacrylate (PMMA) or polystyrene (PS), a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, and/or a blend thereof.

A connection electrode CM may be located on the first organic insulating layer 115. Here, the connection electrode CM may be connected to the drain electrode DE or the source electrode SE through a contact hole of the first organic insulating layer 115. The connection electrode CM may include a highly conductive material. The connection electrode CM may include a conductive material including Mo, Al, Cu, Ti, etc. and may include layers or a single layer including the conductive materials described above. For example, the connection electrode CM may have a multi-layered structure of Ti/Al/Ti.

The second organic insulating layer 116 may be located on the connection electrode CM. The second organic insulating layer 116 may cover the connection electrode CM. The second organic insulating layer 116 may include the same material as the first organic insulating layer 115, or may include a different material from the first organic insulating layer 115.

A light-emitting diode may be located on the second organic insulating layer 116. For example, an organic light-emitting diode OLED may be located on the second organic insulating layer 116. Alternatively, in one or more embodiments, an inorganic light-emitting diode, etc. may also be located on the second organic insulating layer 116.

The organic light-emitting diode OLED may emit red, green, or blue light, or red, green, blue, or white light. The organic light-emitting diode OLED may include a first electrode 211, an emission layer 212b, a functional layer 212f, a second electrode 213, and a capping layer 215. The first electrode 211 may be a pixel electrode (for example, an anode) of the organic light-emitting diode OLED, and the second electrode 213 may be an opposite electrode (for example, a cathode) of the organic light-emitting diode OLED.

The first electrode 211 may be located on the second organic insulating layer 116. The first electrode 211 may be electrically connected to the connection electrode CM through a contact hole defined in the second organic insulating layer 116. The first electrode 211 may include conductive oxide, such as indium tin oxide (ITO), indium zinc oxide (IZO), zinc oxide (ZnO), indium oxide (In₂O₃), indium gallium oxide (IGO), or aluminum zinc oxide (AZO). According to one or more embodiments, the first electrode 211 may include a reflective layer including Ag, Mg, Al, Pt, Pd, Au, Ni, Nd, Ir, Cr, or a compound thereof. According to one or more embodiments, the first electrode 211 may further include a layer including ITO, IZO, ZnO, or In₂O₃ above/below the reflective layer described above. For example, the first electrode 211 may have a multi-layered structure of ITO/Ag/ITO.

A pixel-defining layer 118 having an opening exposing at least a portion of the first electrode 211 may be located on the first electrode 211. The opening defined in the pixel-defining layer 118 may define an emission area of light emitted from the organic light-emitting diode OLED. For example, a width of the opening may correspond to a width of the emission area.

The pixel-defining layer 118 may include an organic insulating material. Alternatively, the pixel-defining layer 118 may include an inorganic insulating material, such as SiNₓ, SiON, or SiOₓ. Alternatively, the pixel-defining layer 118 may include an organic insulating material and an inorganic insulating material. According to some embodiments, the pixel-defining layer 118 may include a light-blocking material. The light-shielding material may include a resin or paste including carbon black, a carbon nano-tube, and/or a black dye, a metal particle, such as Ni, Al, Mo, and/or an alloy thereof, a metal oxide particle (for example, chromium oxide), a metal nitride particle (for example, chromium nitride), or the like. When the pixel-defining layer 118 includes the light-shielding material, reflection of external light due to metal structures arranged below the pixel-defining layer 118 may be reduced.

A spacer 119 may be located on the pixel-defining layer 118. The spacer 119 may include an organic insulating material, such as polyimide. Alternatively, the spacer 119 may include an inorganic insulating material, such as SiNₓ or SiO₂, or may include an organic insulating material and an inorganic insulating material.

According to one or more embodiments, the spacer 119 may include the same material as the pixel-defining layer 118. In this case, the pixel-defining layer 118 and the spacer 119 may be formed together by a mask process using a half-tone mask, etc. Alternatively, the spacer 119 may include a different material from the pixel-defining layer 118.

The emission layer 212b may be located in the opening of the pixel-defining layer 118. The emission layer 212b may include a high molecular-weight or low molecular-weight organic material for emitting a corresponding color of light.

The functional layer 212f may include a first functional layer 212a and a second functional layer 212c. The first functional layer 212a may be located between the first electrode 211 and the emission layer 212b, and the second functional layer 212c may be located between the emission layer 212b and the second electrode 213. However, at least one of the first functional layer 212a or the second functional layer 212c may be omitted. Hereinafter, the disclosure will be described in detail mainly based on the case where each of the first functional layer 212a and the second functional layer 212c is located.

The first functional layer 212a may include a hole transport layer (HTL) and/or a hole injection layer (HIL). The second functional layer 212c may include an electron transport layer (ETL) and/or an electron injection layer (EIL). The first functional layer 212a and/or the second functional layer 212c may be a common layer(s) formed to entirely cover the substrate 100, like the second electrode 213 to be described below.

The second electrode 213 may be located on the functional layer 212f. The second electrode 213 may include a conductive material having a low work function. For example, the second electrode 213 may include a (semi-) transparent layer including Ag, Mg, Al, Pt, Pd, Au, Ni, Nd, Ir, Cr, Li, Ca, or an alloy thereof. Alternatively, the second electrode 213 may further include a layer, such as ITO, IZO, ZnO, or In₂O₃, on the (semi-) transparent layer including the material described above.

According to one or more embodiments, a capping layer 215 may be located on the second electrode 213. The capping layer 215 may include LiF, an inorganic material, and/or an organic material.

An encapsulation layer 300 may be located on the organic light-emitting diode OLED. The encapsulation layer 300 may cover the organic light-emitting diode OLED. The encapsulation layer 300 may be located on the second electrode 213 and/or the capping layer 215. According to one or more embodiments, the encapsulation layer 300 may include at least one inorganic encapsulation layer and at least one organic encapsulation layer. FIG. 3 illustrates that the encapsulation layer 300 may include a first inorganic encapsulation layer 310, an organic encapsulation layer 320, and a second inorganic encapsulation layer 330 that are sequentially stacked.

The first and second inorganic encapsulation layers 310 and 330 may include one or more inorganic materials from among Al₂O₃, TiO, TA₂O₅, HfO₂, ZnO, SiOₓ, SiNₓ, or SiON. The first and second inorganic encapsulation layers 310 and 330 may include a single layer or layers including the materials described above. The organic encapsulation layer 320 may include a polymer-based material. The polymer-based material may include acryl-based resins, epoxy-based resins, polyimide, polyethylene, etc. According to one or more embodiments, the organic encapsulation layer 320 may include acrylate.

An input-sensing layer 400 may be located on the encapsulation layer 300. The input-sensing layer 400 may include a first touch-insulating layer 410, a second touch-insulating layer 420, a first conductive layer 430, a third touch-insulating layer 440, a second conductive layer 450, and a planarization layer 460.

According to one or more embodiments, the first touch-insulating layer 410 may be located on the second inorganic encapsulation layer 330, and the second touch-insulating layer 420 may be located on the first touch-insulating layer 410. According to one or more embodiments, the first touch-insulating layer 410 and the second touch-insulating layer 420 may include an inorganic insulating material and/or an organic insulating material. For example, the first touch-insulating layer 410 and the second touch-insulating layer 420 may include an inorganic insulating material, such as SiOₓ, SiNₓ, and/or SiON.

According to one or more embodiments, at least one of the first touch-insulating layer 410 or the second touch-insulating layer 420 may be omitted. For example, the first touch-insulating layer 410 may be omitted. In this case, the second touch-insulating layer 420 may be located on the second inorganic encapsulation layer 330, and the first conductive layer 430 may be located on the second touch-insulating layer 420.

The first conductive layer 430 may be located on the second touch-insulating layer 420, and the third touch-insulating layer 440 may be located on the first conductive layer 430. According to one or more embodiments, the third touch-insulating layer 440 may include an inorganic insulating material and/or an organic insulating material. For example, the third touch-insulating layer 440 may include an inorganic insulating material, such as SiOₓ, SiNₓ, and/or SiON.

The second conductive layer 450 may be located on the third touch-insulating layer 440. A touch electrode TE of the input-sensing layer 400 may be provided as a structure in which the first conductive layer 430 and the second conductive layer 450 are connected to each other. Alternatively, the touch electrode TE may be formed on any one layer of the first conductive layer 430 and the second conductive layer 450, and may include a metal line provided in the corresponding conductive layer. Each of the first conductive layer 430 and the second conductive layer 450 may include at least one of Al, Cu, Ti, Mo, or ITO, and may include a single layer or layers including the material described above. For example, each of the first conductive layer 430 and the second conductive layer 450 may have a three-layered structure of a Ti layer/an Al layer/a Ti layer.

According to one or more embodiments, the planarization layer 460 may cover the second conductive layer 450. The planarization layer 460 may include an organic insulating material.

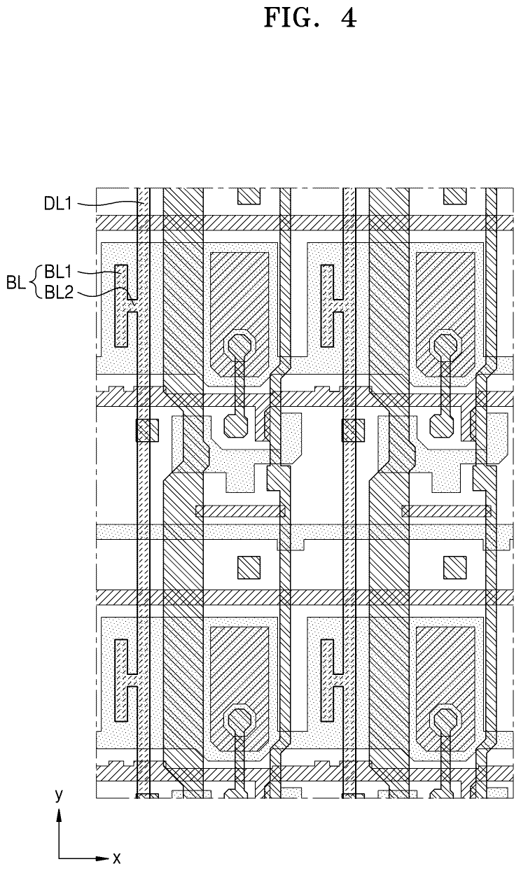

FIG. 4 is a schematic enlarged plan view of the first data line DL1 and the branch line BL of FIG. 1.

According to one or more embodiments, the first data line DL1 arranged in the first display area DA1 (see FIG. 1) may extend in a second direction (for example, a y direction or a −y direction). The branch line BL may be arranged in the first display area DA1, may be connected to the first data line DL1, and may protrude from the first data line DL1 in a first direction (for example, an x direction or a −x direction). The first data line DL1 and the branch line BL may be located on the same layer as each other, and may include the same material as each other.

The branch line BL may include the first branch line BL1 and the second branch line BL2. The first branch line BL1 may extend in the second direction. The second branch line BL2 may connect the first branch line BL1 with the first data line DL1, and may extend in the first direction.

In the case of a display apparatus having an amorphous shape, a capacitor is formed by separately providing lines in some areas, to reduce the load of a data signal transmitted to the pixel circuit PCm (see FIG. 1). When the capacitor is formed by separately providing the lines in some areas, the peripheral area PA (see FIG. 1), which is a non-display area, is increased, and a ratio of the display area DA (see FIG. 1) realizing a display with respect to the display apparatus is decreased.

According to one or more embodiments, the branch line BL may be arranged in the display area DA to be connected to the first data line DL1, and to protrude from the first data line DL1 in the first direction, and the capacitor may be formed of the branch line BL and the first data line DL1, and thus, the load of a data signal transmitted to the pixel circuit PCm may be reduced, and expansion of the peripheral area PA, which is the non-display area, may be reduced or prevented.

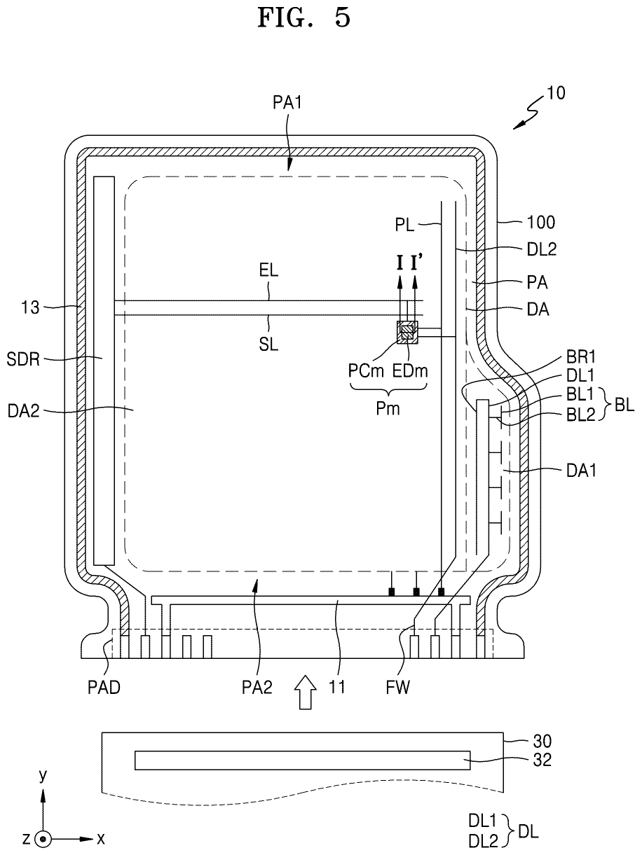

FIG. 5 is a schematic plan view of a portion of the display apparatus 10 according to one or more embodiments. FIG. 6 is a schematic enlarged plan view of a first data line, a first bridge line, and a branch line of FIG. 5.

Referring to FIGS. 5 and 6, a first data line DL1 extending in a second direction (for example, a y direction or a −y direction) may be arranged in the first display area DA1. A branch line BL may be connected to the first data line DL1, and may protrude from the first data line DL1 in a first direction (for example, an x direction or a −x direction). The branch line BL may include a first branch line BL1 extending in the second direction, and a second branch line BL2 connected to the first branch line BL1 and the first data line DL1, and extending in the first direction.

A first bridge line BR1 may be arranged in the first display area DA1, may be apart from the first data line DL1 in the first direction (for example, the x direction or the −x direction), and may extend in the second direction (for example, the y direction or the −y direction). The first bridge line BR1 may be connected to the first data line DL1. In detail, an end of the first bridge line BR1 may be connected to an end of the first data line DL1 adjacent thereto.

The first data line DL1 and the first bridge line BR1 may be located on the same layer as each other, and may include the same material as each other. In detail, the first data line DL1, the branch line BL, and the first bridge line BR1 may be located on the same layer as one another, and may include the same material as one another.

According to one or more embodiments, capacitors may be formed not only between the first data line DL1 and the branch line BL, but also between the first data line DL1 and the first bridge line BR1, and thus, the load of a data signal transmitted to the pixel circuits PCm may be efficiently reduced, and expansion of the peripheral area PA, which is a non-display area, may be reduced or prevented.

A thickness of the first bridge line BR1 in the first direction (for example, the x direction or the −x direction) may be greater than a thickness of the first data line DL1 in the first direction (for example, the x direction or the −x direction). The thickness of the first bridge line BR1 may be greater than the thickness of the first data line DL1, and thus, an increased capacitor may be formed between the first bridge line BR1 and the first data line DL1. Thus, the load of a data signal transmitted to the pixel circuits PCm may be efficiently reduced, and expansion of the peripheral area PA, which is the non-display area, may be reduced or prevented. However, the disclosure is not limited thereto. The thickness of the first bridge line BR1 in the first direction may be the same as or substantially the same as the thickness of the first data line DL1 in the first direction.

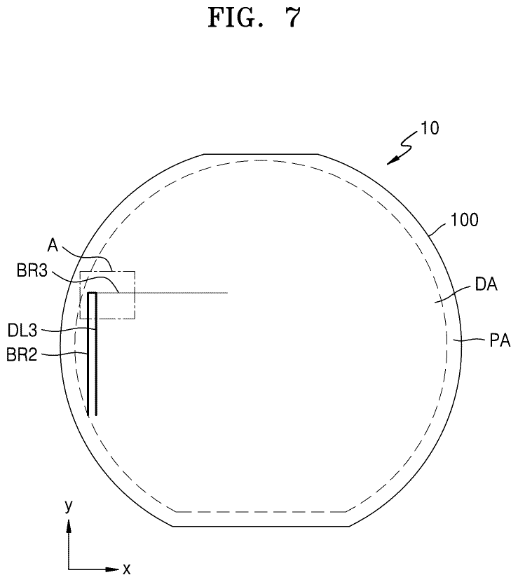

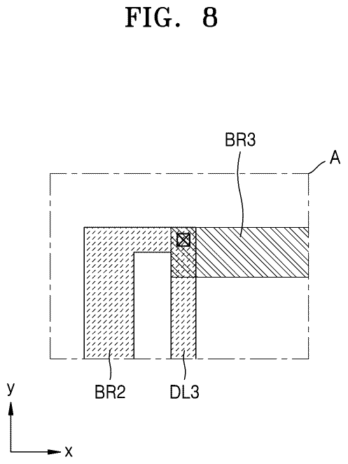

FIG. 7 is a schematic plan view of the display apparatus 10 according to one or more embodiments. FIG. 8 is a schematic enlarged plan view of region A of FIG. 7. In detail, FIG. 8 is a schematic enlarged view of portions of a third data line DL3, a second bridge line BR2, and a third bridge line BR3 of FIG. 7.

Referring to FIGS. 7 and 8, the display apparatus 10 may have a circular shape. In other words, the display area DA of the display apparatus 10 may have a circular shape. The peripheral area PA may be arranged to surround at least a portion of the display area DA having the circular shape.

The third data line DL3 extending in a second direction (for example, a y direction or a −y direction) may be arranged in the display area DA having the circular shape. The second bridge line BR2 may be arranged to be apart from the third data line DL3 in a first direction (for example, an x direction or a −x direction), and may extend in the second direction. The third data line DL3 and the second bridge line BR2 may be connected to each other. In detail, an end of the third data line DL3 may be connected with an end of the second bridge line BR2 adjacent thereto. The third data line DL3 and the second bridge line BR2 may be located on the same layer as each other, and may include the same material as each other.

According to one or more embodiments, the third bridge line BR3 connected to an end of the third data line DL3, and extending in the first direction, may be arranged in the display area. The third bridge line BR3 and the third data line DL3 may be located on different layers from each other, and may be connected to each other through a contact hole.

Capacitors may be formed between the third data line DL3 and the second and third bridge lines BR2 and BR3, and thus, the load of a data signal transmitted to the pixel circuit PCm (see FIG. 1) may be reduced, and expansion of the peripheral area PA, which is a non-display area, may be reduced or prevented.

According to one or more embodiments, a thickness of the second bridge line BR2 in the first direction may be greater than a thickness of the third data line DL3 in the first direction. Also, a thickness of the third bridge line BR3 in the second direction may be greater than the thickness of the third data line DL3 in the first direction. The thickness of the second bridge line BR2 and the thickness of the third bridge line BR3 may be greater than the thickness of the third data line DL3, and thus, increased capacitors may be formed between the third data line DL3 and the second and third bridge lines BR2 and BR3. Thus, the load of a data signal transmitted to the pixel circuit PCm may be efficiently reduced, and expansion of the peripheral area PA, which is a non-display area, may be reduced or prevented. However, the disclosure is not limited thereto. The thickness of the second bridge line BR2 in the first direction may be the same as or substantially the same as the thickness of the third data line DL3 in the first direction. The thickness of the third bridge line BR3 in the second direction may be the same as, or substantially the same as, the thickness of the third data line DL3 in the first direction.

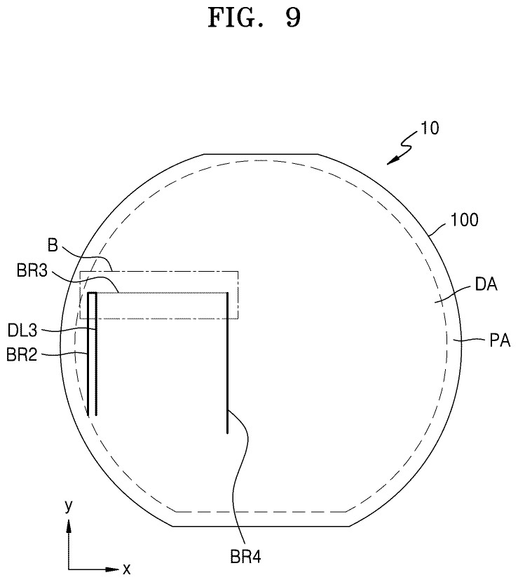

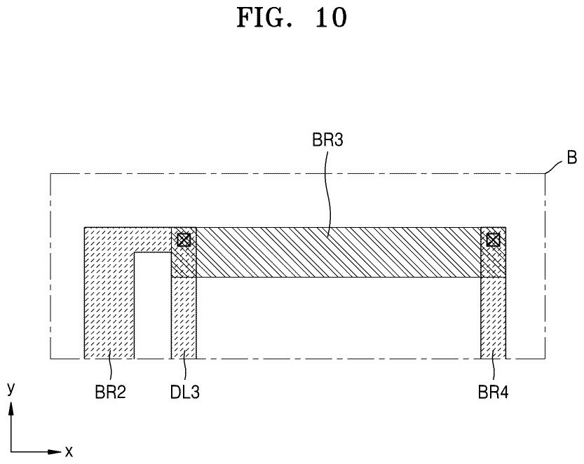

FIG. 9 is a schematic plan view of the display apparatus 10 according to one or more embodiments. FIG. 10 is a schematic enlarged plan view of region B of FIG. 9.

Referring to FIGS. 9 and 10, according to the one or more embodiments corresponding to FIGS. 7 and 8, a fourth bridge line BR4 connected to the third bridge line BR3, and extending in the second direction (for example, the y direction or the −y direction), may be additionally arranged in the display area DA. The fourth bridge line BR4 may be arranged to be apart from the third data line DL3 in the first direction (for example, the x direction or the −x direction). Also, the third data line DL3 may be arranged between the second bridge line BR2 and the fourth bridge line BR4.

The third bridge line BR3 and the fourth bridge line BR4 may be located on different layers from each other. The third bridge line BR3 and the fourth bridge line BR4 may be connected to each other through a contact hole. However, the fourth bridge line BR4 and the third data line DL3 may be located on the same layer as each other, and may include the same material as each other. In detail, the third data line DL3, the second bridge line BR2, and the fourth bridge line BR4 may be located on the same layer as one another, and may include the same material as one another.

According to one or more embodiments, there may be formed, not only the capacitors between the third data line DL3 and the second and third bridge lines BR2 and BR3, but also a capacitor between the third data line DL3 and the fourth bridge line BR4. Thus, the load of a data signal transmitted to the pixel circuits PCm may be efficiently reduced, and expansion of the peripheral area PA, which is the non-display area, may be reduced or prevented.

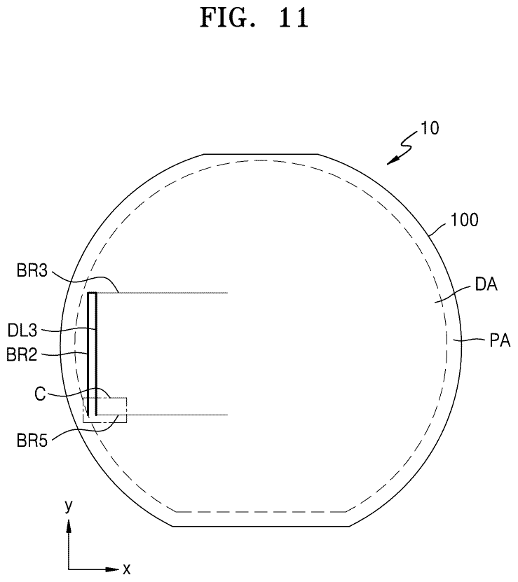

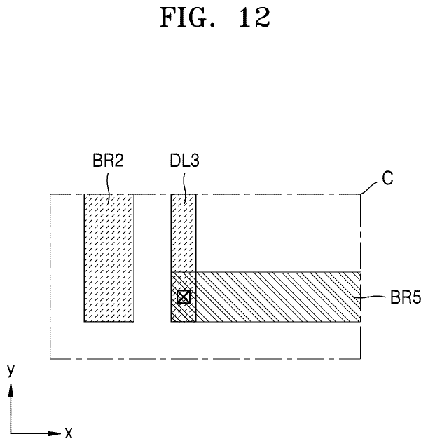

FIG. 11 is a schematic plan view of the display apparatus 10 according to one or more embodiments. FIG. 12 is a schematic enlarged plan view of region C of FIG. 11.

Referring to FIGS. 11 and 12, according to the one or more embodiments corresponding to FIGS. 7 and 8, a fifth bridge line BR5 connected to the other end of the third data line DL3, and extending in the first direction (for example, the x direction or the −x direction), may further be provided in the display area DA. The fifth bridge line BR5 may be located on a different layer from the third data line DL3, and the fifth bridge line BR5 and the third data line DL3 may be connected to each other through a contact hole.

There may be formed, not only the capacitors between the third data line DL3 and the second and third bridge lines BR2 and BR3, but also a capacitor between the third data line DL3 and the fifth bridge line BR5. Thus, the load of a data signal transmitted to the pixel circuits PCm (see FIG. 1) may be efficiently reduced, and expansion of the peripheral area PA, which is the non-display area, may be reduced or prevented.

In the case of a display apparatus having an amorphous shape, a capacitor is formed by separately providing lines in some areas, to reduce the load of a data signal transmitted to the pixel circuit PCm. When the capacitor is formed by separately providing the lines in some areas, the peripheral area PA, which is a non-display area, is increased, and a ratio of the display area DA realizing a display with respect to the display apparatus is decreased.

According to embodiments, the branch line BL and the bridge lines BR connected to the first data line DL1 may be arranged in the display area DA, and thus, the capacitors may be formed between the first data line DL1 and the branch line BL and the bridge line BR. Thus, the load of a data signal transmitted to the pixel circuits PCm may be reduced, and expansion of the peripheral area PA, which is the non-display area, may be reduced or prevented.

As described above, according to the one or more of the above embodiments, the display apparatus having improved reliability and quality may be realized. However, the scope of the disclosure is not limited to these effects as described above.

It should be understood that embodiments described herein should be considered in a descriptive sense only and not for purposes of limitation. Descriptions of aspects within each embodiment should typically be considered as available for other similar aspects in other embodiments. While one or more embodiments have been described with reference to the figures, it will be understood by one of ordinary skill in the art that various changes in form and details may be made therein without departing from the spirit and scope as defined by the following claims, with functional equivalents thereof to be included therein.

What is claimed is:

1. A display apparatus comprising:
a substrate comprising a display area, and a peripheral area surrounding at least a portion of the display area in plan view;
a first data line in the display area, and extending in a second direction;
a second data line apart from the first data line in a first direction crossing the second direction, extending in the second direction, and having a length that is greater than a length of the first data line; and
a branch line connected to the first data line, and protruding from the first data line in the first direction.

2. The display apparatus of claim 1, wherein the branch line comprises a first branch line extending in the second direction, and a second branch line connecting the first branch to the first data line and extending in the first direction.

3. The display apparatus of claim 1, wherein the first data line and the branch line are at a same layer, and comprise a same material.

4. The display apparatus of claim 1, further comprising a first bridge line apart from the first data line in the first direction and extending in the second direction,
wherein the first data line and the first bridge line are connected to each other.

5. The display apparatus of claim 4, wherein an end of the first bridge line is connected to an end of the first data line.

6. The display apparatus of claim 4, wherein the first data line and the first bridge line are at a same layer, and comprise a same material.

7. The display apparatus of claim 4, wherein a thickness of the first bridge line in the first direction is greater than a thickness of the first data line in the first direction.

8. A display apparatus comprising:
a substrate comprising a display area having a circular shape, and a peripheral area surrounding at least a portion of the display area in plan view;
a third data line arranged in the display area, and extending in a second direction; and
a second bridge line apart from the third data line in a first direction crossing the second direction, extending in the second direction, and connected to the third data line.

9. The display apparatus of claim 8, wherein an end of the third data line is connected to an end of the second bridge line.

10. The display apparatus of claim 8, wherein the third data line and the second bridge line are at a same layer, and comprise a same material.

11. The display apparatus of claim 8, wherein a thickness of the second bridge line in the first direction is greater than a thickness of the third data line in the first direction.

12. The display apparatus of claim 8, further comprising a third bridge line connected to a first end of the third data line, and extending in the first direction.

13. The display apparatus of claim 12, wherein the third bridge line and the third data line are at different respective layers.

14. The display apparatus of claim 12, wherein a thickness of the third bridge line in the second direction is greater than a thickness of the third data line in the first direction.

15. The display apparatus of claim 12, further comprising a fourth bridge line apart from the third data line in the first direction, extending in the second direction, and connected to the third bridge line.

16. The display apparatus of claim 15, wherein the third data line is arranged between the second bridge line and the fourth bridge line.

17. The display apparatus of claim 15, wherein the third bridge line and the fourth bridge line are at different respective layers.

18. The display apparatus of claim 15, wherein the fourth bridge line and the third data line are at a same layer, and comprise a same material.

19. The display apparatus of claim 15, further comprising a fifth bridge line connected to a second end of the third data line, and extending in the first direction.

20. The display apparatus of claim 19, wherein the fifth bridge line and the third data line are at different respective layers.
